(19) United States
(12) Patent Application Publication
(10) Pub. No.: US 2005/0052639 A1
(43) Pub. Date: Mar. 10, 2005

(54) Light barrier arrangement

(75) Inventor: Paul Hartl, Munich (DE)

Correspondence Address: VENABLE, BAETJER, HOWARD AND CIVILETTI, LLP, P.O. BOX 34385, WASHINGTON, DC, 20043-9998, US

(73) Assignee: Leuze Iumiflex GmbH & Co. KG, Furstenfeldbruck (DE)

(21) Appl. No.: 10/933,470

(22) Filed: Sep. 3, 2004

(30) Foreign Application Priority Data
Sep. 5, 2003 (DE) 103 41 007.4

(51) Int. Cl. H01L 29/06; H01L 31/0328; H01L 31/0336; H01L 31/072; H01L 31/109; G01C 1/00; G01B 11/26

(52) U.S. Cl. 356/139.03

(57) ABSTRACT

A light-barrier arrangement for monitoring objects in a monitoring region, includes at least one transmitter for emitting light beams, at least one receiver for receiving the transmitted light beams, at least one evaluation unit for generating an object detection signal in dependence on received signals present at the receiver output and an interface for reading parameter values into the evaluation unit. The interface unit includes a transponder for providing a non-contacting input of parameter values into the evaluation unit.

### CROSS-REFERENCE TO RELATED APPLICATION

This application claims the priority of German Patent Application No. 103 41 007.4, filed on Sep. 5, 2003, the subject matter of which is incorporated herein by reference.

### BACKGROUND OF THE INVENTION

The invention relates to a light-barrier arrangement for monitoring objects in a monitoring region. Such a light-barrier includes at least one transmitter for emitting light beams, at least one receiver for receiving the transmitted light beams and at least one evaluation unit for generating an object detection signal in dependence on received signals present at the receiver output.

A light-barrier arrangement of this type is known from German patent document DE 100 46 863 C1. The light-barrier arrangement disclosed therein is provided with an interface for the input of parameter values, wherein the interface has an external interface element and an interface component that comprises a first optoelectronic communication device and a magnetically actuated switch. The magnetically actuated switch can be a reed contact in the simplest case. The first communication device and the magnetically activated switch cooperate with the external interface element which can be attached to the interface component of the light-barrier arrangement, wherein the external interface element is provided with an associated second optoelectronic communication device and a magnet for activating the switch. The first communication device comprises a light-transmitting element and a light-receiving element which make possible an infrared coupling between the external interface element and the light-barrier arrangement. The communication device for the first interface element contains either a pair of light transmitting and light receiving elements or a light-conducting device, for example a light-conducting fiber, a prism, or an arrangement of mirrors for feeding back light, transmitted by the first communication device, to its light-receiving element.

The light-transmitting element and the light-receiving element, as well as the magnetically actuated switch, are arranged behind a light and magnetic-wave permeable cover plate. The magnet preferably is strong enough, so that the external interface element, and if necessary also the cable, can be held solely by magnetic forces against an upright standing cover plate for the light-barrier arrangement.

With the external interface element that is attached to the light-barrier arrangement, the magnet activates the switch for the interface component. As a result, the light-barrier arrangement changes to a mode of operation in which the values are parameterized

The process to parameterize makes it possible to input parameter values into the light-barrier arrangement, for example via a configuration/diagnostic device that is connected to the external interface element, such as a personal computer, wherein the data exchange occurs via the optoelectronic communication devices of the interface.

### SUMMARY OF THE INVENTION

It is therefore an object of the present invention to modify a light-barrier arrangement of the aforementioned type, such that the expenditure to parameterize is further reduced.

The above and other objects are accomplished according to one embodiment of the invention by the provision a light-barrier arrangement for monitoring objects in a monitoring region, comprising: at least one transmitter for emitting light beams; at least one receiver for receiving the transmitted light beams; at least one evaluation unit for generating an object detection signal in dependence on signals present at the receiver output; and an interface for reading parameter values into the evaluation unit, the interface including a transponder for providing a non-contacting input of parameter values into the evaluation unit.

The light-barrier arrangement according to the invention is used for monitoring objects in a monitoring region. The primary advantage of the invention is that a transponder is used for the non-contacting input of parameter values into the light-barrier arrangement, without any expenditure for installation or adjustment. For this, the transponder only needs to be moved toward the light-barrier arrangement, up to a predetermined limit distance, so that the signals containing parameter values can be input via the transponder into the light-barrier arrangement. As a result, a fixation of the transponder and therewith associated mechanical and adjustment expenditure are no longer necessary.

The fact that the transponder is a purely passive element which does not require its own energy supply is an advantage of the interface according to the invention. Energy may thus be supplied to the transponder by the light-barrier arrangement.

According to another exemplary embodiment, the light-barrier arrangement is provided with an antenna, by means of which activation signals are read into the transponder if it is within the specified limit distance. The activation signals, which preferably take the form of radar signals, function as control signals that trigger the transmission of signals containing parameter values by the transponder, wherein the transmission of activation signals also ensures the energy supply of the transponder.

The transponder, which is provided with a transmitting unit, preferably transmits signals containing at least one code to the light-barrier arrangement. It is particularly advantageous if the transponder emits radar signals, in the same way as the antenna for the light-barrier arrangement, which can be received again by the light-barrier arrangement antenna itself. This type of embodiment is distinguished by a particularly simple and cost-effective design. The transponder according to an alternative embodiment can also emit optical signals, inductive signals, or the like. In that case, a corresponding receiving unit is additionally integrated into the light-barrier arrangement for receiving the signals emitted by the transponder.

The codes emitted by the transponder contain the information necessary to parameterize the light-barrier arrangement, wherein physical adjustment variables can be specified for this parameterizing of the light-barrier arrangement, e.g. the transmitting capacities of the transmitter or transmitters or the amplification values of the signals received by the receiver or receivers.

For the simplest design, the light-barrier arrangement can be a single light barrier, wherein the term light barrier comprises one-way light barriers as well as reflection light barriers. The light-barrier arrangement furthermore can consist of a multiple arrangement of such light barriers, wherein it is particularly advantageous if the light-barrier arrangement is designed as light grid or light curtain.

In those cases where the light-barrier arrangement is a light grid with an arrangement of several pairs of transmitters and receivers that define the axes of light beams, a predetermined number of beam axes can be blanked out for parameterizing the light grid. With a light grid where no blanking occurs, an object detection signal is generated if at least one beam axis is interrupted by an interfering object. For numerous applications, however, objects which do not present a safety hazard, such as machine parts or the like, are positioned in the monitoring region that is formed by the beam axes of the light grid. The detection of these objects should not result in generating an object detection signal.

To ensure that no object-detection signal is generated, the respective beam axes can be blanked out in a learning process, so that an interruption of these blanked axes no longer result in generating an object detection signals. Such learning processes for blanking out beam axes of a light grid can be activated by transmitting corresponding codes via the transponder.

According to another advantageous embodiment, the codes emitted by the transponder can contain different access authorizations which are evaluated in the evaluation unit. Depending on the access values contained in the respective code, only a defined set of parameters can be learned with the transponder, wherein such a hierarchical dispensing of access rights is advantageous in particular for light-barrier arrangements used in the field of security technology where specific security critical parameters should be learned only by authorized security personnel.

### BRIEF DESCRIPTION OF THE DRAWINGS

The invention is explained in the following with the drawings, wherein the enclosed schematic drawings show the following:

FIG. 1 illustrates a first exemplary embodiment of a light grid for detecting objects within a monitoring region;

FIG. 2 shows a light grid according to FIG. 1 with two blanked out beam axes.

### DETAILED DESCRIPTION OF THE INVENTION

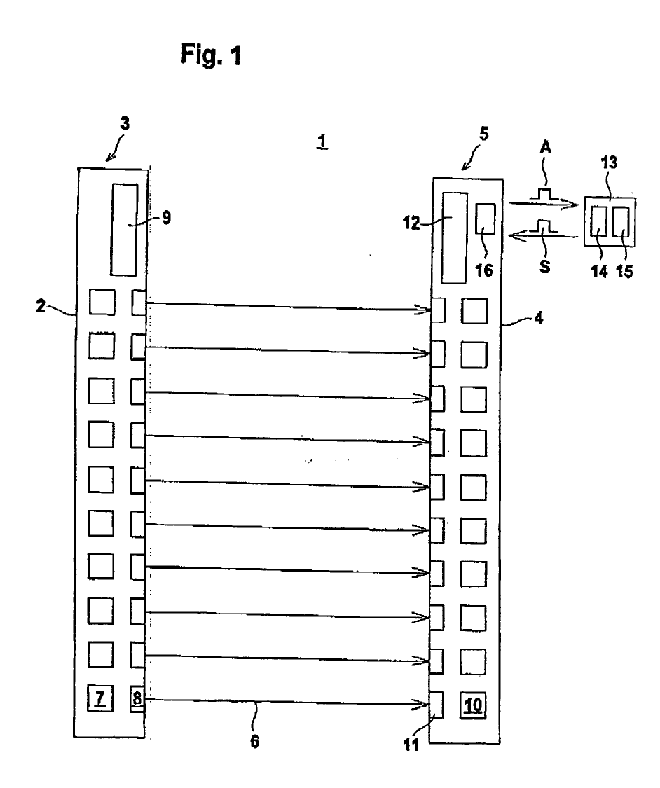

FIG. 1 shows the design of a light grid 1 for monitoring a region. The light grid 1 comprises a transmitting unit 3, integrated into a first housing 2, and a receiving unit 5 that is integrated into a second housing 4. The transmitting unit 3 and the receiving unit 5 are located at opposite edges of the monitoring region.

The transmitting unit 3 comprises an arrangement of transmitters 7 for emitting light beams 6. The transmitters 7 preferably consist of identically embodied light-emitting diodes, disposed evenly spaced apart and side-by-side, wherein the transmitters 7 are preferably arranged equidistant along a straight line. A transmitting optic 8 is installed upstream of each transmitter 7 for forming the transmitting light beams 6. The transmitting optics 8 are arranged in the region of the front wall of housing 2, behind an exit window that is not shown separately. The transmitters 7 in the present case emit light beams 6 in the infrared range. In principle, the transmitters 7 can also emit light beams 6 in a visible wavelength range.

The optical axes of the transmitted light beams 6 run parallel to each other in the plane for the monitoring region.

A transmitter control unit 9 is used to actuate the transmitters 7, wherein a pulsed mode is used for operating the transmitters 7 of the present embodiment. The transmitters 7 thus emit light pulses with a specified pulse-pause ratio. The individual transmitters 7 cyclically emit successive light pulses, the timing of which is controlled by the transmitter control unit 9. In the process, the transmitters 7 are activated successively during one scanning cycle in a predetermined scanning direction, based on their positioning sequence in the transmitting unit 3. The transmitting light pulses from the first transmitter 7 function to synchronize the light grid 1. It is useful if the light pulses from the first transmitter 7 are provided for this with a coding that clearly differs from the coding of the light pulses from the remaining transmitters 7.

The receiving unit 5 is provided with an arrangement of identically designed, side-by-side arranged receivers 10. The receivers 10 preferably comprise respectively one photodiode and are disposed equidistant along a straight line. A receiving optic 11 is positioned upstream of each receiver 10, wherein respectively one receiver 10 is arranged opposite one transmitter 7 of the transmitting unit 3. For the present case, the transmitting light beams 6 are formed in such way that with a clear optical path, the transmitting light beams 6 of a transmitter 7 respectively impinge only on the opposite-arranged receiver 10. Each beam axis of light grid 1 is formed by one transmitter 7 and the receiver 10 assigned to it.

The receivers 10 are controlled via a receiver control unit 12. The signals present at the receiver 10 output are evaluated in an evaluation unit which forms a component of the receiver control unit 12. With a clear optical path for the light grid 1, the transmitted light beams 6 arrive unobstructed at the associated receiver 10 where they generate a reference receiving signal that corresponds to a clear optical path. In particular, a threshold value is used for evaluating the signals received in the evaluation unit, wherein the amplitudes for the reference receiving signals are above the threshold value.

If an object enters the monitoring region, the optical path for the light a beam 6 from by at least one transmitter 7 is interrupted. The signal received at the associated receiver 10 is consequently below the threshold value, meaning no reference receiving signal is recorded at the associated receiver 10.

The interruptions of the optical axes are evaluated in the evaluation unit for generating an object detection signal. The object detection signal is generated as a binary switching signal with switching intervals “0” and “1.” The switching state “0” corresponds to a clear optical path for light grid 1, meaning no object was recorded in the control unit. The switching state “1” corresponds to an object interruption in the optical path for light grid 1. Preferably, the interruption of one beam axis should be sufficient for an object intervention. By generating an object detection signal of this type, a command is generated for shutting down a machine or system for which the surrounding area is monitored with the aid of a light grid 1.

The light grid 1 thus forms a device for protecting persons by preventing a person from entering the area surrounding a machine while it is in operation.

In principle, the light grid 1 can also be designed as transceiver. In that case, the transmitters 7 of transmitting unit 3 and the receivers 10 of receiving unit 5 are disposed inside a joint housing which is arranged at the edge of a monitoring region. A reflector is arranged at the opposite edge of the monitoring region, by means of which the beams 6, emitted by the transmitters 7, are reflected back to the associated receivers 10 if the optical path for the light grid 1 is clear.

For the light grid 1 according to FIG. 1, a command for shutting down the machine is issued if an optional beam axis of light grid 1 is interrupted.

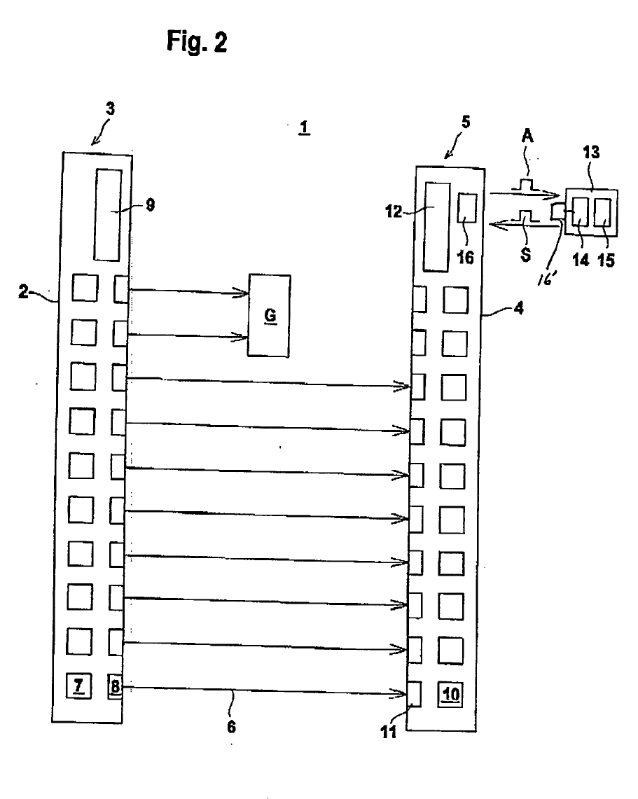

FIG. 2 shows a variant of the evaluation process for generating an object detection signal. FIG. 2 shows an object G, disposed in the monitoring region of light grid 1, which leads to an interruption of the first two beam axes of light grid 1. This object G can be a column, for example, or a component of the machine to be monitored. An object of this type does not represent a safety-critical object. If a shutdown command is generated by the light grid 1 upon detecting such a non safety-critical object, it would lead to an unnecessary machine shutdown. Thus, such regions of light grid 1 are advantageously blanked out in a learning process prior to the startup of light grid 1. If an object interrupts a blanked out beam axis, the switching signal does not change to the switching mode 1 and no shutdown command is issued for the machine. A shutdown command is generated only if a safety-critical object enters the portion of the monitoring region that is not blanked out. The blanking out therefore permits a differentiation between safety-critical and non safety-critical objects. In general, the blanked out areas within the monitoring region can involve differing numbers of beam axes. The blanking regions can also vary with respect to time and, finally, several blanked-out regions can be provided within the monitoring region.

Blanked-out regions of this type, as well as other characteristic parameters of the light grid 1, are assigned through the parameterizing of light grid 1. The parameterizing is realized with an interface for the non-contacting input of parameter values into the light grid 1.

The interface for the non-contacting input comprises a transponder 13 provided with one transmitting unit 14 and one storage unit 15. The transmitting unit 14 for the exemplary embodiment is a transponder antenna that emits signals S, which in the present case are radar signals. The storage unit 15 is a microchip or the like. Coded signals are stored in this storage unit 15 and are transmitted by means of the transmitting unit 14.

The transponder 13 cooperates with an antenna 16 that is connected to the evaluation unit. For realizing the parameterizing, an operator will move the transponder 13 closer to the light grid 1, up to a predetermined limit distance.

Following this, the antenna 16 of light grid 1 transmits activation signals A to the transponder 13.

In the present case, the transmitting unit 14 of transponder 13 is designed as transmitting/receiving unit, so that the activation signals A can be received with the transponder antenna. In principle, the transponder 13 can also be provided with separate antennas 16′ for receiving the activation signals A and emitting signals.

The antenna 16′ supplies energy to the transponder 13 along with the transmission of the activation signals A. As a result, the transponder 13 can be embodied as purely a passive element, without its own energy supply.

Once the activation signals A are received, the transponder 13 emits the signals S for parameterizing. The signals S contain at least one code that is stored in the storage unit 15, wherein the code can be entered into the transponder 13 with the aid of a programming device that is not shown herein.

The antenna 16 is embodies as transmitting/receiving antenna for receiving the signals S. In principle, a separate receiving antenna can also be provided for receiving the signals S.

The transponder 13 design is not limited to transmitting units 14 being embodied as antennas 16.

The transponder 13, for example, can also be used to emit inductive signals S. In that case, toroidal coils or the like are provided for the transmitting unit 14 and energy for the transponder 13 is again supplied via the light grid 1, wherein suitable coil arrangements are connected to the evaluation unit for transmitting the activation signals A.

The code read by the transponder 13 into the evaluation unit contains information for realizing the parameterizing of light grid 1. Parameters of this type, which are input via the transponder 13, generally can comprise physical adjustment variables for the light grid 1 which include, in particular, the transmitting capacities of transmitter 7 and/or the amplifications of the signals received at the receivers 10 of light grid 1. By varying these parameters, the light grid 1 operation can be adapted, for example, to different and application-specific distances between the transmitting unit 3 and the receiving unit 5.

Information on how to blank out areas of light grid 1 can be transmitted as additional parameter values. The parameter values preferably comprise control commands that initiate a learning process for defining the areas to be blanked out. In principle, the mode of operation for blanking out areas can also be determined along with the parameter values. For example, the minimum and maximum number of beam axes within a blanking region, or the maximum number of blanking regions within a monitoring region can be determined via the parameter values. In a subsequent learning process, the parameter values can furthermore be used to define whether the areas are blanked out permanently or only at certain times.

It is advantageous if the code in the transponder 13 also contains an individual access authorization. Depending on this access authorization, specific parameter sets only can be learned for the light grid 1. Issuing such access authorization codes will prevent unauthorized persons from entering parameter values for the light grid 1.

As soon as an activation signal (A) is sent out, a code is transmitted by the transponder 13 and recorded in the evaluation unit, which then initially checks the access authorization. If the access authorization is acceptable, the light grid 1 is switched by way of the evaluation unit from its normal operating mode to a parameterizing mode in which the parameterizing of the light grid 1 is activated based on the input code.

In the simplest case, the light grid 1 switches back to the operating mode without feedback, following the parameterizing. Alternatively, the light grid 1 can also be provided with a display unit which indicates the start and end of a parameterizing operation.

According to one advantageous embodiment, parameterizing data, in particular the blanked-out regions set during a learning process, can be read out via the antenna 16 as feedback for the code that is input by the transponder 13. The status of the realized parameterizing of light grid 1 is thus available in the transponder 13 and, for control purposes, can be read out of the transponder 13 with a programming device.

The invention has been described in detail with respect to referred embodiments, and it will now be apparent from the foregoing to those skilled in the art, that changes and modifications may be made without departing from the invention in its broader aspects, and the invention, therefore, as defined in the appended claims, is intended to cover all such changes and modifications that fall within the true spirit of the invention.

1. A light-barrier arrangement for monitoring objects in a monitoring region, comprising:
at least one transmitter for emitting light beams;
at least one receiver for receiving the transmitted light beams;
at least one evaluation unit for generating an object detection signal in dependence on received signals present at the receiver output; and
an interface for reading parameter values into the evaluation unit, the interface including a transponder for providing a non-contacting input of parameter values into the evaluation unit.

2. The light-barrier arrangement according to claim 1, wherein the evaluation unit includes an antenna for transmitting activation signals to the transponder when the transponder is positioned within a limit distance to the antenna.

3. The light-barrier arrangement according to claim 1, wherein the transponder is supplied with energy via the antenna.

4. The light-barrier arrangement according to claim 2, wherein the transponder comprises a transmitting unit and a storage unit coupled to the transmitting unit and storing at least one code, wherein following an activation signal that is recorded in the storage unit of the transponder, the at least one code stored in the storage unit is transmitted via the transmitting unit to parameterize the light-barrier arrangement.

5. The light-barrier arrangement according to claim 4, wherein the transmitting unit comprises a transmitting/receiving unit, and wherein following the transmitting of the code by the antenna at least one feedback signal is transmitted to the transponder.

6. The light-barrier arrangement according to claim 5, wherein the feedback signal contains information relating to the operation to parameterized the light-barrier arrangement.

7. The light-barrier arrangement according to claim 5, wherein the transmitting unit of the transponder includes a transponder antenna.

8. The light-barrier arrangement according to claim 4, wherein the transponder is adapted to receive the at least one code by a programming device.

9. The light-barrier arrangement according to claim 4, wherein the at least one code contains an individual access authorization which is checkable in the evaluation unit.

10. The light-barrier arrangement according to claim 4, wherein the at least one code contains different parameter values.

11. The light-barrier arrangement according to claim 10, wherein the at least one code contains different parameter sets, each set being dependent on an access authorization.

12. The light-barrier arrangement according to claim 1, the parameter values include physical adjustment variables.

13. The light-barrier arrangement according to claim 12, wherein the physical adjustment variables include at least one of (1) a transmitting capacity of the at least one transmitter and (2) amplification of a signal received by the at least one receiver.

14. The light-barrier arrangement according to claim 1, wherein the at least one transmitter and the at least one receiver comprise a light grid having a specified number of transmitter/receiver pairs, and wherein transmitted light beams are emitted by individual transmitters and guided onto the associated receivers and form beam axes of the light grid.

15. The light-barrier arrangement according to claim 14, wherein the evaluation unit generates an object detection if at least one beam axis is interrupted as a result of an object intervention.

16. The light-barrier arrangement according to claim 14, wherein at least one of the beam axes of the light grid can be blanked out so that object interruption of the at least one blanked out beam axis does not lead to generation of an object detection signal.

17. The light-barrier arrangement according to claim 16, wherein the blanking of beam axes is learned in a teaching process that is triggered via the transponder.

18. The light-barrier arrangement according to claim 17, wherein the beam axes, blanked out during the learning process, are read into the transponder as feedback to the emitted code.
